(19) United States
(12) Patent Application Publication
(10) Pub. No.: US 2011/0103137 A1
(43) Pub. Date: May 5, 2011

(54) SOURCE CONTROLLED SRAM

(75) Inventor: Robert Charles Beat, Bristol (GB)

(73) Assignee: SILICON BASIS LTD, BRISTOL (GB)

(21) Appl. No.: 12/992,505

(22) PCT Filed: May 13, 2009
(86) PCT No.: PCT/GB2009/001194

§ 371 Date: Jan. 13, 2011

(30) Foreign Application Priority Data
May 13, 2008 (GB) 0808699.3

(51) Int. Cl. G11C 11/40

(52) U.S. Cl. 365/156

(57) ABSTRACT

Disclosed is a cmos sram cell including two cross-coupled inverters, each having a pmos and an nmos transistor, a first signal line connected to the sources of each of the nmos transistors, a second signal line, parallel to the first signal line, and connected to the source of one of said pmos transistors, and a third signal line connected to the source of the other of said pmos transistors. The third signal line may be orthogonal to the first and second signal lines. Also disclosed is a cmos sram cell including two cross-coupled inverters, a pair of bitlines for writing data to the cell, and at least one further bitline for reading data from the cell.

The present invention relates to Static Random Access Memory (SRAM). In particular, though not exclusively, the invention relates to new SRAM cell designs which improve on failings of traditional SRAM cells.

SRAM is a type of semiconductor memory that retains its content as long as power remains applied. Locations in the SRAM memory can be written to or read from in any order, regardless of the memory location that was last accessed. SRAM, rather than other sorts of memory such as, for example, dynamic RAM (DRAM), is often used in circuits where either speed or low power (or both) are specifically required. As such, SRAM is used in many different applications ranging from, for example, RAM or cache memory in microcontrollers and microprocessors, in application specific integrated circuits (ASICs), in field programmable gate arrays (FPGAs), and embedded in personal computers, workstations, LCD screens and printers.

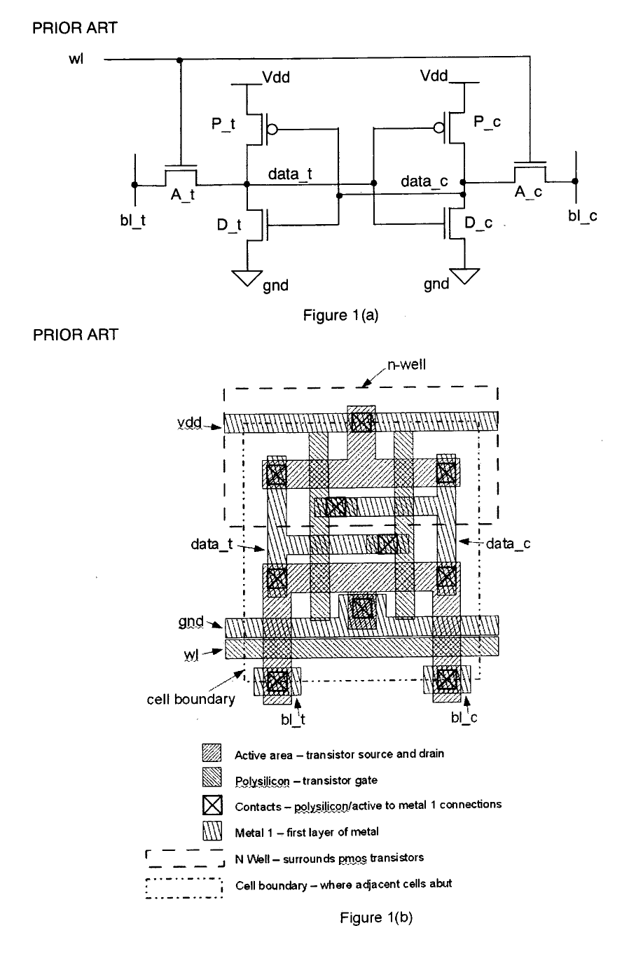

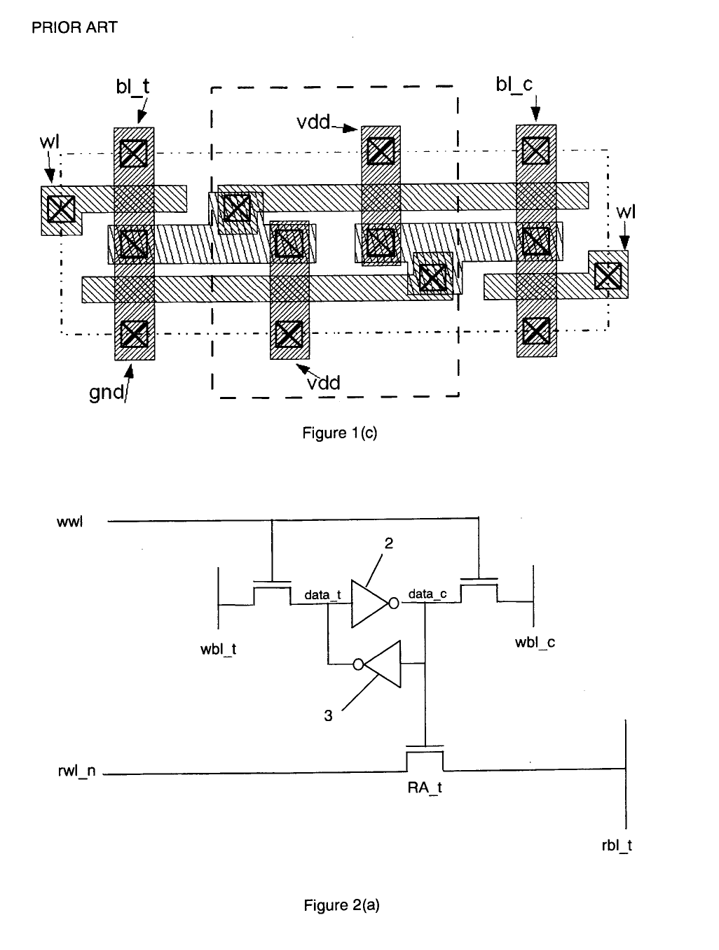

Most SRAMs today utilise the so-called “6T” cell illustrated in FIG. 1(a). This consists of six CMOS transistors including four transistors (P_t, P_c, D_t, D_c) that form two cross-coupled inverters. These are two pmos transistors (P_t, P_c) and two nmos drive transistors (D_t, D_n). This storage cell has two stable states that are used to denote 0 and 1, and two additional access transistors (A_t, A_c) which serve to control the access to a storage cell during read and write operations. This cell can thus store one memory bit. A wordline (wl) is used to select a row of such 6T cells in an array of such cells. The wordline controls the two access transistors (A_t, A_c) which, in turn, control whether the cell should be connected to true (bl_t) and complement (bl_c) bitlines. In a two dimensional array of cells the wordlines of a row of cells are connected together so that selecting the wordline selects the whole row. The bitlines of the cells in the two dimensional array are connected orthogonally to the wordlines. Usually the bitlines are precharged to the supply voltage Vdd ready for a read or write operation.

In a read, the cell selected by having its wordline raised to Vdd will pull either the true (bl_t) or complement (bl_c) bitline low creating a differential voltage on the bitline pair. This differential voltage can be sensed by an amplifier (the senseamp—not shown in FIG. 1(a)) connected to the column which recovers the read data (data_t, data_c) to full rail (vdd and gnd). Often column multiplexing is employed to select one of a set of columns to connect to the senseamp.

To write, the wordline is selected and full rail write data is driven onto the bitlines by write drivers circuits: to write 1, bl_t is driven to Vdd and bl_c to gnd, and visa versa to write 0.

FIG. 1(b) shows a typical layout of the prior art 6T cell, together with a key defining the differently shaded areas. (This key is also applicable to the layout diagrams of FIGS. 1(c), 6 to 9, 11, 18, 20, 21 and 25.) There are many variations. Sometimes the cell is split vertically and each half mirrored in the y-axis so instead of sharing a ground (gnd) and power supply (vdd) voltage connection in the centre of the cell, they are shared with the cells to the left and right.

An alternative layout, show in Error! Reference source not found. 1(c) puts the nmos on either side of the pmos devices in the cell. This produces a cell with all the transistors running in the same direction, making it easier to manufacture. However, having two well boundaries i.e. two pmos/nmos pairs facing each other, tends to increase the area of the cell, depending on the design rules of the manufacturing process to be used.

This cell design has been used for many years, but there are some issues affecting the performance of this cell in modern semiconductor processes. One such problem is that the wordline access devices (A_t, A_c) leak. This is a problem in itself because it increases the current consumption in standby mode, where the SRAM is powered up but is not being accessed. It is also potentially a problem in the operation of the SRAM. In a pathological case all cells on a bitline may store 0 except the one desires to read, which stores 1. Reading that cell discharges bl_c, but all the other cells are seeing full Vdd across the access device A_t because the bitline is precharged and data_t=gnd. Thus, there is a leakage path through all the A_t access devices in the other cells which can add up to reduce or even overtake the differential building on the other, actively read, bitline. This slows, or even corrupts the data being read. To circumvent this problem the number of cells per bitline column is often reduced and the resulting sub-bitlines are connected hierarchically. However, the extra peripheral circuitry involved in doing this increases area, power consumption and complexity.

The leakage through the access devices is exacerbated by reverse narrow width effect (see Shigeki Ohbayashi et al “A 65-nm SoC Embedded 6T-SRAM Designed for Manufacturability with Read and Write Operation Stabilizing Circuits”, IEEE Journal of Solid-state Circuits, April 2007, volume 42, number 4 pp. 820-829). This physical effect on small nmos devices causes their threshold voltage (Vtn) to be lower than normally sized devices. Lower Vtn means higher leakage.

The pmos transistors (P_t, P_c) also have an effect. Stronger pmos devices give a more stable cell, but if they are too strong the cell is more difficult to write to: the bitline write driver has to drive a long highly capacitive bitline, then through the weak access devices (A_t, A_c) and finally over-drive the pmos device. If the pmos devices are too strong, writes may fail.

Cell stability is often quantified by a metric known as static noise margin (SNM). The SNM of a particular cell design can be simulated: the higher the SNM, the more stable and more immune to noise the cell is.

The worst case operating point for stability of the traditional 6T cell is when wordline=Vdd and both bitlines=Vdd. This occurs during read or write when a column on a selected row is not being read or written but the bitlines are held precharged at Vdd. These conditions are collectively known has half-select. The SNM during half-select is usually much lower than during unselected states (i.e. when the wordline is gnd). Worst case SNM also occurs at the very start of a read operation, before the read has a chance to build differential on the bitline.

SNM also reduces with Vdd: the lower the Vdd, the lower the SNM. Manufacturing process variations across a given SRAM array cause a distribution of SNM: some cells in the array have lower SNM. On some cells, the SNM is so bad that the cell fails to operate. These so called soft fails are therefore proportional to Vdd (as opposed to hard fails which fail at all Vdd values and are related to physical defects with the cell). The stability of the cell during half-select limits the minimum voltage at which the SRAM can operate, because below that voltage soft-fails cause unacceptable yield loss.

Soft-fails are increasing as process geometries shrink causing higher variability in transistor performance within a chip. H. Pilo, C Barwin et al in “An SRAM Design in 65-nm Technology Node Featuring Read and Write-Assist Circuits to Expand Operating Voltage”, IEEE Journal of Solid-state Circuits, April 2007, volume 42, number 4 pp. 813-819, estimate that soft fails overtake hard fails between the 90 nm and 65 nm process generations. This is due to the transistor dimensions (oxide thicknesses, channel lengths etc.) approaching atomic levels. Any variations intrinsic to the manufacturing process will have a proportionally bigger effect on the smallest transistors on the chip. SRAMs are particularly badly hit by the on chip variations because they contain these very small transistors, notably the access and P-load devices.

Various solutions to all these problems have been proposed, but most involve an increase in the area of the SRAM cell or its peripheral circuits, or both.

It is an aim of the present invention to avoid or minimise one or more of the foregoing disadvantages.

According to a first aspect of the present invention there is provided a CMOS SRAM cell comprising two cross-coupled inverters, a pair of bitlines for writing data to the cell, and at least one further bitline for reading data from the cell.

For the avoidance of doubt it will be understood that the term “CMOS” as used herein is intended to include known extensions of CMOS such as BiCMOS.

The cell may comprise a single said further bitline for reading data from the cell (hereinafter referred to as the “read bitline”). In this case, the cell may further comprise a pair of access transistors for accessing the cell during write operations on the cell (hereinafter referred to as the “write transistors”), in use thereof, and a further access transistor (hereinafter referred to as the “read transistor”) via which said read bitline accesses the cell during read operations on the cell, in use thereof. Preferably, the cell further includes a write wordline for controlling the pair of write transistors and a separate read wordline for controlling the read transistor. Preferably, said read wordline is connected to the source of the read transistor and said read bitline is connected to the drain of the read transistor. The read transistor may be a pmos transistor or an nmos transistor.

Alternatively, the cell may comprise a pair of said further bitlines (hereinafter referred to as the “read bitlines”) for reading data from the cell (e.g. in a fully differential cell design). In this case, the cell may further comprise a pair of access transistors for accessing the cell during write operations on the cell (hereinafter referred to as the “write transistors”), in use thereof, and a further pair of access transistors (hereinafter referred to as the “read transistors”) via which said pair of read bitlines access the cell respectively during read operations on the cell. Preferably, the cell further includes a write wordline for controlling the pair of write transistors and a separate read wordline for controlling the pair of read transistors. Preferably, said read wordline is connected to the source of each of the read transistors and each said read bitline is connected to the drain of a respective one of the read transistors. The read transistors may each be pmos transistors or may each be nmos transistors.

It will be appreciated that in CMOS SRAMs, each cross-coupled inverter preferably comprises a pmos transistor and a complementary nmos transistor. In another possible embodiment of the invention, the two write bitlines are connected to the sources of two like transistors respectively of the inverters. The cell preferably further includes a write wordline connected to the sources of the other two like transistors respectively of the inverters. For example, the write bitlines may be connected to the sources of the two nmos transistors respectively of the inverters and the write wordline may be connected to the source of each of the pmos transistors.

Alternatively, the write wordline may be connected to the sources of the nmos transistors and the two write bitlines may be connected to the sources of the two pmos transistors respectively of the inverters.

In these latter two embodiments the cell preferably further comprises at least one access transistor (hereinafter referred to as the or each “read transistor”) via which the or each said read bitline (for reading data from the cell) accesses the cell during read operations on the cell, in use thereof. Preferably, the cell further includes a dedicated read wordline for controlling the or each said read transistor. Preferably, said read wordline is connected to the source of the or each said read transistor and the or each said read bitline is connected to the drain of a respective said read transistor.

One significant advantage of said latter two embodiments is that they do not require access transistors to control the write bitlines. This improves the leakage performance of the cell: there is no longer a path from the precharged bitline to the low data node via the access transistors. In addition, access devices are generally very small for the following reasons: (1) In order to keep the overall cell size small; and (2) To make the nmos beta ratio high enough to make the cell stable. The beta ratio is the ratio of the beta, or current drive strength of the drive transistor, divided by the beta of the access transistor. The higher the beta ratio, the more stable the cell. As a general rule beta ratio should be around 1.5. Small devices such as these are more prone to device variations. Thus removing the (write) access devices from the cell produces a large improvement in cell variability across a memory.

According to a second aspect of the invention there is provided a CMOS SRAM cell comprising two cross-coupled inverters each comprising a pmos and an nmos transistor, a first signal line connected to the sources of each of the nmos transistors, a second signal line, parallel to the first signal line, and connected to the source of one of said pmos transistors, and a third signal line connected to the source of the other of said pmos transistors, wherein the third signal line is orthogonally connected to the first and second signal lines.

When a multiplicity of such cells are arranged in an array a significant advantage of the cell according to this second aspect of the invention is that half selected cells (on the rest of the row and column containing the cell) are exposed to smaller voltage variations than in the previous arrangement (according to the first aspect of the invention). This can have benefits in keeping the SNM of the half selected cells at an acceptable level.

Instead of having the true and complement source connections to the pmos transistors run orthogonally it would alternatively be possible to design the cell such that the true and complement source connections to the nmos transistors run orthogonally. Thus, according to a third aspect of the invention there is provided a CMOS SRAM cell comprising two cross-coupled inverters each comprising a pmos and an nmos transistor, a first signal line connected to the sources of each of the pmos transistors, a second signal line, parallel to the first signal line, and connected to the source of one of said nmos transistors, and a third signal line connected to the source of the other of said nmos transistors, wherein the third signal line is orthogonally connected to the first and second signal lines.

According to a fourth aspect of the invention there is provided an array of substantially identical CMOS SRAM cells according to the second or third aspect of the invention, wherein the array includes at least four parallel signal lines for accessing different cells in a row of the array, wherein each line of a first pair of said signal lines is connected to the sources of respective ones of the nmos transistors in said row and each line of a second pair of said signal lines is connected to the sources of respective ones of the pmos transistors in said row. Consequently, any given cell in the row may be accessed using the respective two of said signal lines to which the given cell is connected. Where four said parallel signal lines are provided it will be appreciated that utilising this design may allow one of every four cells in the row to be selected.

In another possible embodiment the cell may be configured such that the true and complement source connections to the both the mos transistors and the pmos transistors run orthogonally. Thus, according to a fifth aspect of the invention there is provided a CMOS SRAM cell comprising two cross-coupled inverters each comprising a pmos and an nmos transistor, a first pair of parallel signal lines comprising a first line connected to the source of one of the pmos transistors and a second line connected to the source of one of the nmos transistors, and a second pair of parallel signal lines comprising a first line connected to the source of the other of said nmos transistors and a second line connected to the source of the other of said pmos transistors and wherein said two pairs of signal lines are orthogonal.

In this cell all four transistor sources in the cell are thus separately connected. The n-source signals run orthogonally, as do the p-source signals. This arrangement may reduce the voltages required to write to the cell as differentials are built up on both p-sources and n-sources.

Optionally, the cell according to the second, third, fourth or fifth aspects of the invention may additionally include at least one read transistor for accessing the cell during read operations thereon. The or each read transistor may be a pmos transistor or an nmos transistor. The source of the or each read transistor is preferably connected to a read wordline, while the drain is connected to a read bitline.

Each of the above-described inventions improves on traditional SRAMs in at least one or more of the following ways:
1. Smaller cell area.
2. Lower static power consumption.
3. Faster read access.
4. Separate read and write ports (thus concurrent reads/writes are possible).
5. Low voltage operation.
6. No read leakage, allowing more cells to share a bitline without compromising data integrity.
7. The above leads to further area savings in the SRAM by reducing the area of peripheral circuits.
8. Improved layout: topologically superior layout for better manufacturing control and yields.

Preferred embodiments of the invention will now be described by way of example only and with reference to the accompanying drawings in which:

FIG. 1(a) is a circuit diagram of a conventional 6T SRAM cell;

FIG. 1(b) is a schematic diagram of one possible layout of the prior art 6T cell of FIG. 1(a);

FIG. 1(c) is schematic diagram of an alternative possible layout of the prior art 6T cell of FIG. 1(a);

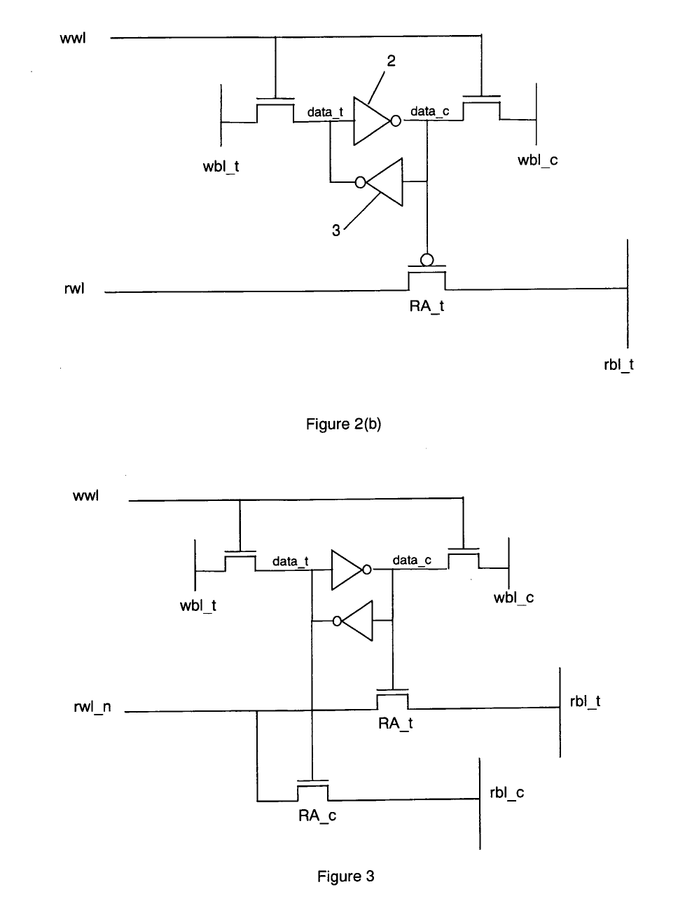

FIG. 2(a) is a circuit diagram of an SRAM cell according to a first embodiment of the invention, incorporating an n-source connected read wordline;

FIG. 2(b) is a circuit diagram of an alternative version of the inventive SRAM cell of FIG. 2(a), incorporating a p-source connected read wordline;

FIG. 3 is a circuit diagram of a fully differential version of the SRAM cell of FIG. 2(a);

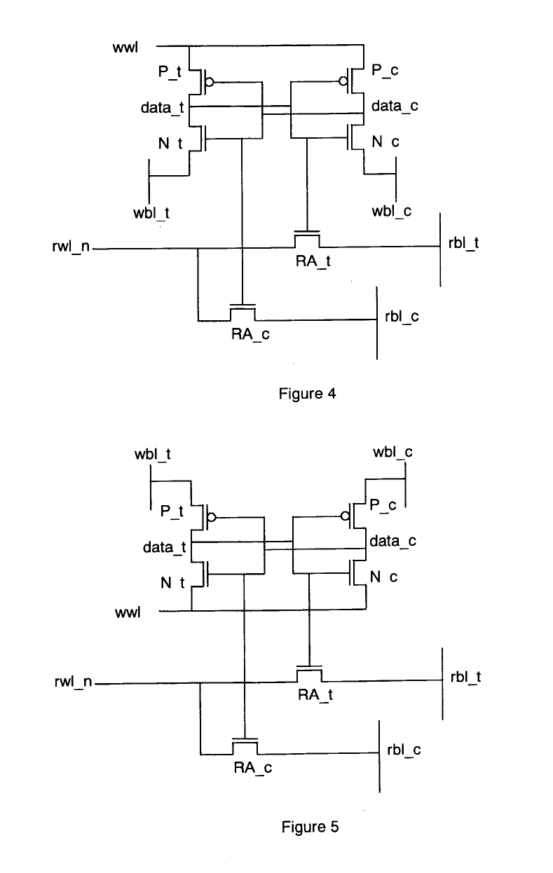

FIG. 4 is a circuit diagram of an SRAM cell according to another embodiment of the invention, incorporating n-source connected write bitlines;

FIG. 5 is a circuit diagram of an alternative version of the cell of FIG. 4, incorporating p-source connected write bitlines;

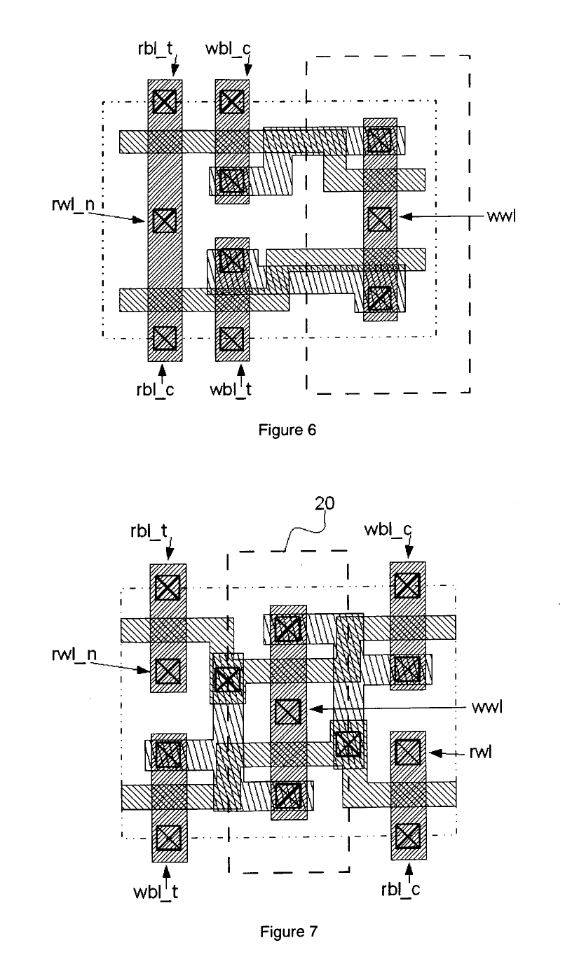

FIG. 6 is a schematic diagram of the layout of a single well boundary, source connected write bitline (NSWB) cell, according to one embodiment of the invention;

FIG. 7 is a schematic diagram of a possible layout of a double well boundary 6T NSWB cell;

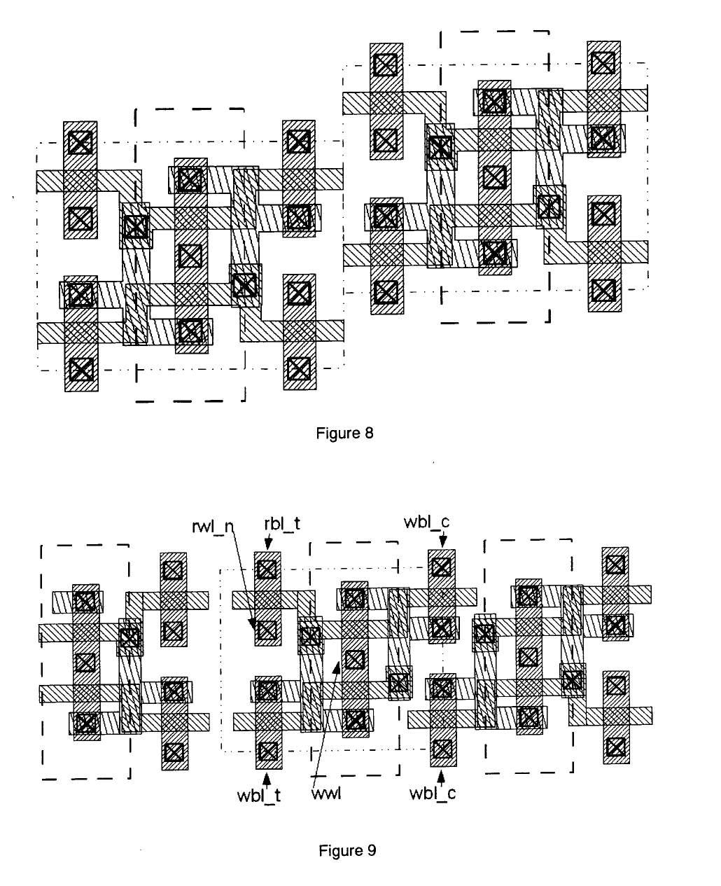

FIG. 8 is a schematic diagram of a possible layout of a staggered double well boundary 6T NSWB cell;

FIG. 9 is a schematic diagram of the layout of a 5T NSWB cell, according to one embodiment of the invention;

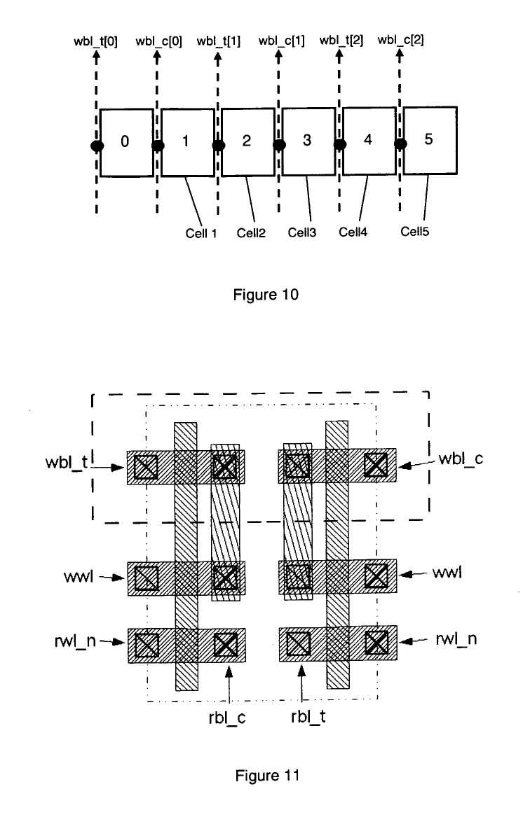

FIG. 10 illustrates a method of reducing half selected bitlines on a source connected write bitline cell, in order to share the vertical bitlines;

FIG. 11 is a schematic diagram of a possible layout of a p-source connected write bitline cell with shared write bitlines;

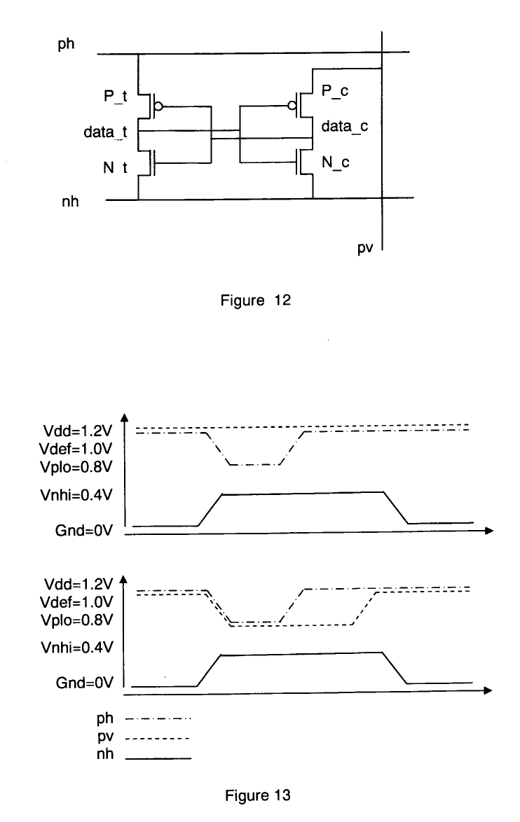

FIG. 12 is a circuit diagram of an SRAM cell according to another embodiment of the invention, incorporating orthogonal true and complement source connections to the pmos transistors;

FIG. 13 is a graph showing two-phase write waveforms for a PSOL4T cell with Vdef=Vdd;

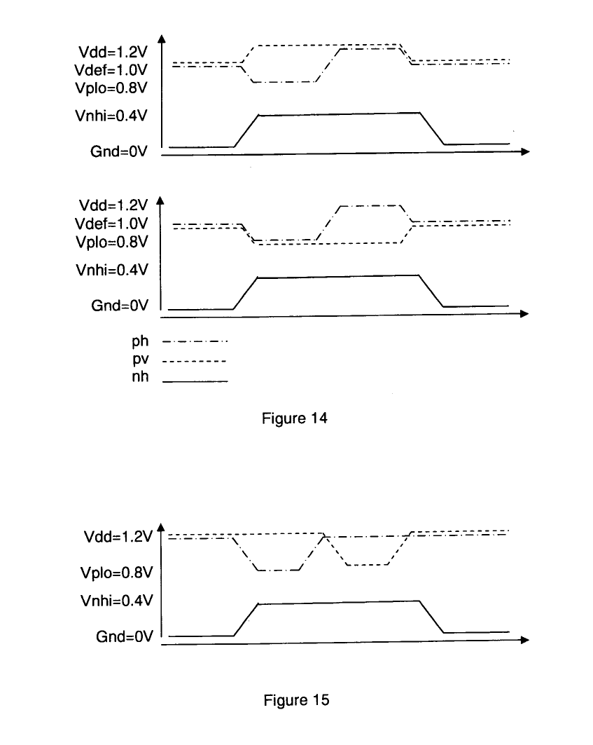

FIG. 14 is a graph showing two-phase write waveforms for a PSOL4T cell with Vdef=1.0V;

FIG. 15 is a graph showing write 0 then selectively write 1 waveforms for a PSOL4T cell with Vdef=1.0V;

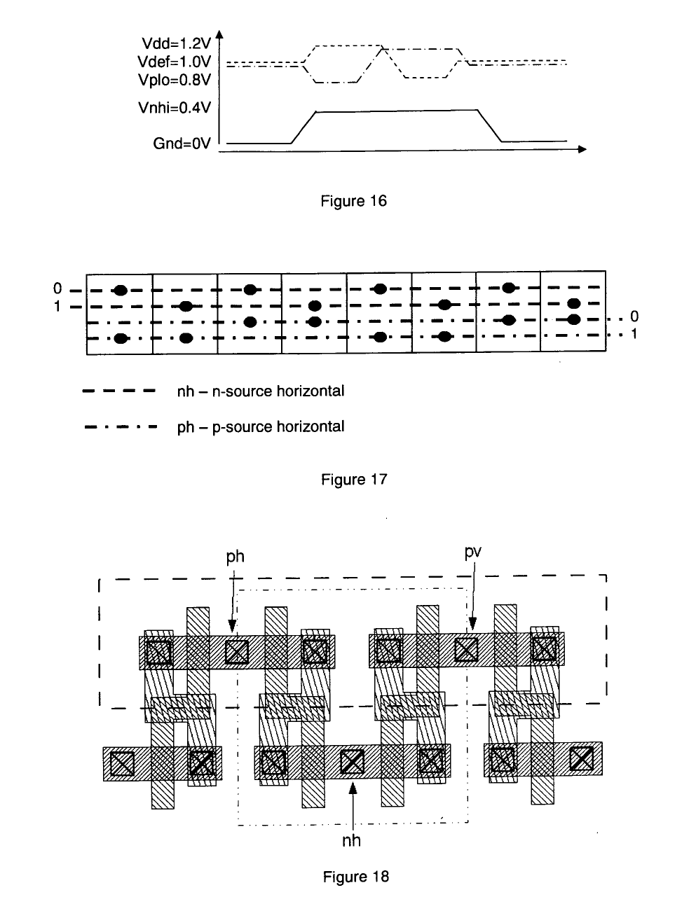

FIG. 16 is a graph showing write 0 then selectively write 1 waveforms for a PSOL4T cell with Vdef=Vdd;

FIG. 17 is a diagram illustrating a horizontal source signal pairing scheme;

FIG. 18 is a schematic diagram of the layout of a single well boundary PSOL4T cell incorporating orthogonal bitlines, according to one embodiment of the invention;

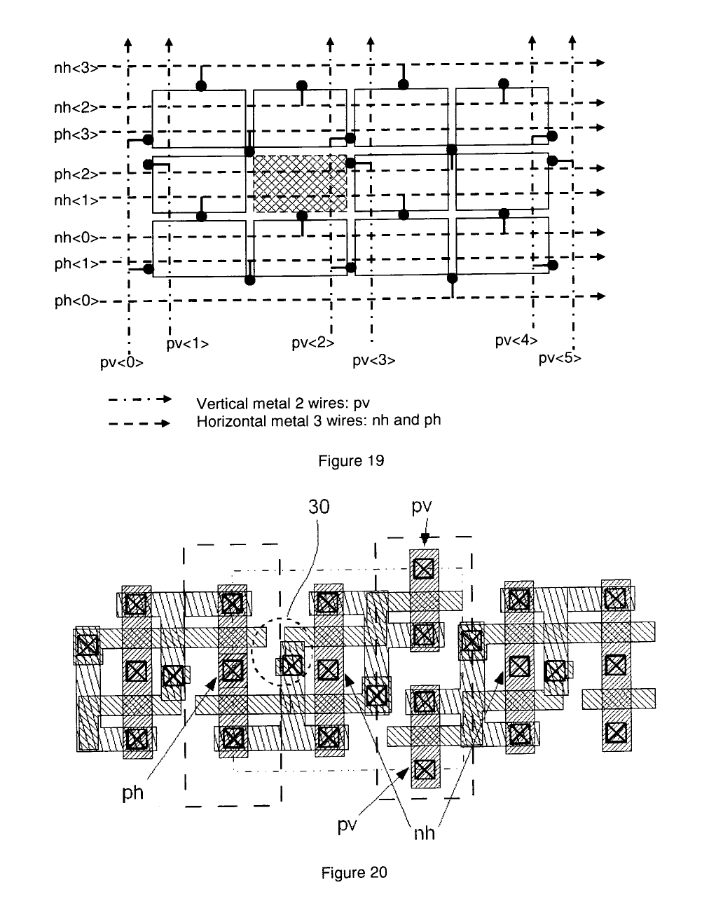

FIG. 19 is a diagram illustrating an array arrangement for an array of single well boundary PSOL4T cells;

FIG. 20 is a schematic diagram of an alternative layout topology of a single well boundary PSOL4T cell to that shown in FIG. 18;

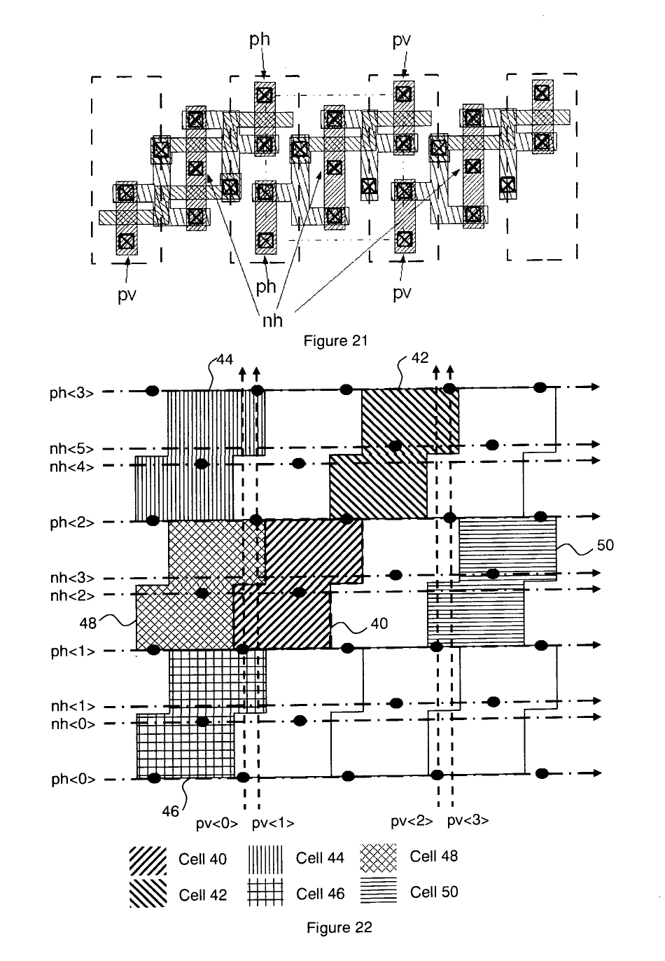

FIG. 21 is a schematic diagram of a possible layout of a double well boundary PSOL4T cell;

FIG. 22 is a diagram illustrating an array arrangement for an array of double well boundary PSOL4T cells;

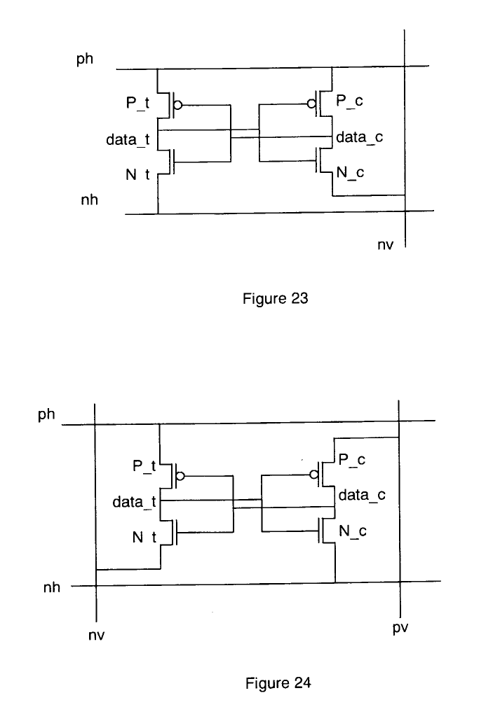

FIG. 23 is a circuit diagram of an alternative version of the cell of FIG. 12, incorporating orthogonal true and complement source connections to the nmos transistors;

FIG. 24 is a circuit diagram of another embodiment of the invention incorporating orthogonal true and complement source connections to the nmos transistors and also to the pmos transistors;

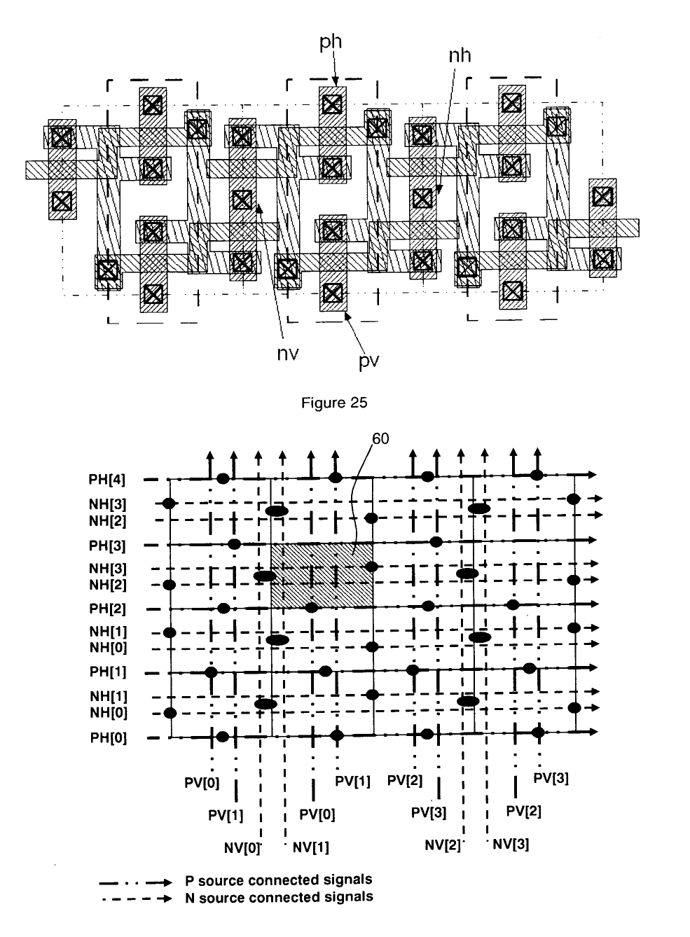

FIG. 25 is a schematic diagram of the layout of a double well boundary SSS4T cell, according to one embodiment of the invention;

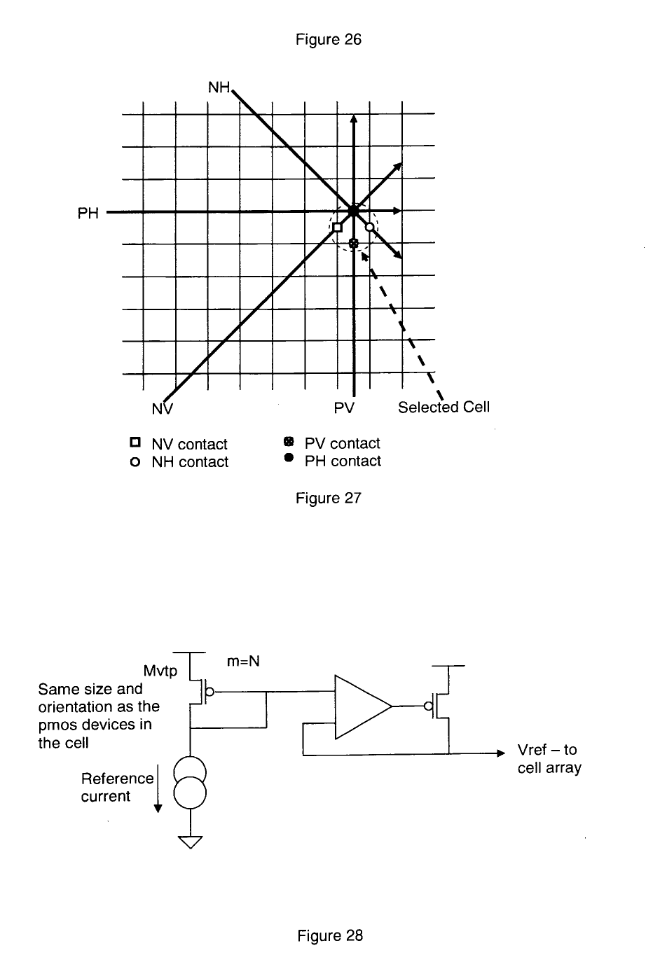

FIG. 26 is a diagram of an array arrangement for an array of double well boundary SSS4T cells like that of FIG. 25;

FIG. 27 is a schematic diagram illustrating the use of diagonal connectivity to select one cell in an array of SSS4T cells; and

FIG. 28 is a circuit diagram of a Vdd−Vtp voltage generator.

### ALTERNATIVE READ MECHANISM

### Source Connected Read Wordline

FIG. 2(a) illustrates an inventive SRAM cell in which an alternative read path has been added (as compared with the traditional 6T cell of FIG. 1) that removes the need to read via the standard bitlines (now referenced as wbl_t, wbl_c), which are now only used for write operations. In the inventive cell of FIG. 2(a) a dedicated read wordline rwl_n is provided. This read wordline rwl_n is connected to the source of a nmos read transistor RA_t whose gate is connected to the (complement) output node data_c of the cross-coupled inverters 2,3. The drain of the read transistor RA_t is connected to a dedicated read bitline rbl_t. A read operation is performed by precharging the read bitline rbl_t to the supply voltage Vdd and then pulling the selected read wordline rwl_n low. If the (complement) output node data_c is high, a current path from the read bitline rbl_t to the write wordline rwl_n is present and the read bitline rbl_t will start to discharge.

Where a multiplicity of the inventive cells of FIG. 2(a) are arranged together in an array, the array is configured such that the read wordline rwl_n selects a row of such cells in the array. Other rows in the array are not activated because even if they also have a 0 stored (and therefore data_c=Vdd) their respective read transistors RA_t will not conduct significant current until there is a threshold voltage Vtn across them (from source to drain). In addition, because the source of the nmos read transistor is connected to the supply voltage Vdd, or near Vdd (Vdd minus the differential), the effective threshold voltage Vtn is inflated by a property of MOS devices known as body effect. As the read discharges rbl_t towards Vdd−Vtn, eventually other cells attached to that bitline will start to turn on. This process will act to clamp the read bitline differential to Vdd−Vtn.

The default stable state (i.e. when not performing a read operation) of the inventive cell structure is thus rwl_n=Vdd and rbl_t=Vdd. Therefore no source drain leakage path exists.

An alternative but similar solution is illustrated in FIG. 2(b) which uses a pmos read transistor RAUt instead of an nmos one. Like parts to the cell of FIG. 2(a) are referenced by like reference numerals. Here, a read is performed by precharging the read bitline rbl_t to ground gnd (not shown) and then pulling the selected read wordline rwl high. If the cross-coupled inverter (complement) output node data_c is low (i.e. gnd) a current path from rbl_t to rwl is present and rbl_t will start to rise.

This new read mechanism allows the cell to be operated at much lower voltages than the traditional 6T design, allowing lower power consumption. This is due to cell stability: as the supply voltage lowers, stability gets worse. The worst case operating point for stability of the traditional 6T cell is half-select: wordline=Vdd and both bitlines=Vdd. This condition is unavoidable at the start of read and therefore limits the minimum voltage at which the 6T cell can operate.

In contrast, in the inventive cells of FIGS. 2(a) and (b), where the (write) access transistors A_t, A_c are not used for read operations, this condition is removed and the cell can safely operate at much lower voltages. B. Calhoun and A. Chandrakasan, in “A 256 kb 65 nm Sub-threshold SRAM Design for Ultra-Low-Voltage Operation”, IEEE Journal of Solid-state Circuits, March 2007, volume 42, number 3 pp. 680-688, showed that a cell that doesn't use the access devices for reads can operate safely down to Vdd/2.

FIG. 2(a) and (b) each show a ‘single ended’ design i.e. non-differential. To read this cell a reference voltage of approximately half the differential of a standard read must be provided by external circuits. Alternatively, this same method can be used in a fully differential design by adding another read transistor, as illustrated in FIG. 3 which utilises an nmos read transistor RA_t. In this case a second read transistor RA_c is provided having its gate connected to the true output node data_t of the cross-coupled inverters 2,3, its source connected to the read wordline rwl_n and its drain to a second (complement) read bitline rbl_c.

Because the read is through a single nmos transistor, the speed at which the differential builds using this technique is better than the traditional 6T cell which will reduce the overall SRAM access time. Also, with the traditional 6T cell the strength of the write access devices A_t, A_c is restricted to ensure the cell is stable: if the access devices A_t, A_c are too strong the cell is susceptible to noise. With the configuration of FIG. 3 there is no such restriction: the size of the read transistors RA_t, RA_c can be set according to a traditional speed/power/area trade off.

A possible disadvantage of this read mechanism may be that the wordline driver has to sink all the currents from the read bitlines. This may limit the number of cells on a wordline, increase the size of the wordline driver or reduce the rate of differential build. However, this will still be faster than a standard 6T cell.

### Alternative Write Mechanism: Source Connected Write Bitlines

An alternative method of writing to the cell is to use source connected bitlines for writes. Instead of having standard access devices, writes are controlled via the sources of the nmos and pmos devices in the cell. Such a cell is illustrated in FIG. 4. In this cell, the write wordline wwl is connected to the pmos sources of all the cells in a row of an array of such cells. The write bitlines wbl_t, wbl_c are connected to the nmos sources of all the cells in a column of the array.

Moving the wbl_t, wbl_c nodes of one cell in this manner (with respect to their positions in the afore-described cells of the types shown in FIGS. 2 and 3) means moving the sources of all the cells in the column across the array. One needs, in use of the cell, to be able to select an individual row in the array: this can be done by lowering the write wordline wwl of the row of cells required. Lowering wwl lowers the threshold of the back-to-back inverters in the cell latch, making them easier to write to than the other cells in the column.

The write wordline, wwl is normally at Vdd, say 1.2V. When a write occurs, the selected wordline is lowered to say 0.8V. To write data to the cell one of the write bitlines, wbl_t (true) or wbl_c (complement) is raised to say 0.4V. For example, let us assume one is writing a 1 to a cell storing a 0. When wbl_t on the source of the true nmos transistor N_t is raised, that voltage will be transferred to the (true) storage node data_t and therefore onto the gate of the other inverter. As the wbl_t voltage rises it will eventually reach the lowered threshold of the other inverter, flipping the cell. In the cells on the other columns the raised source voltage alone is not sufficient to flip the data and therefore they remain intact.

An alternative explanation is that raising wbl_t above Vtn turns on the opposite (i.e. complementary) nmos transistor, N_c. If the row has been selected its write wordline wwl voltage will be lowered. This weakens the (complementary) pmos transistor P_c allowing the respective nmos transistor N_c to pull the complement storage node data_c low. The other cells in the column will have wwl=Vdd and therefore their pmos devices are strong enough to beat the complementary nmos device N_c

If the cell already stores value 1 then the gate of the (true) nmos transistor N_t will be gnd, so the raised wbl_t voltage is not transferred to the data_t node and so the cell will stay at 1.

Lowering the wwl also has the effect of increasing the Vtp (where Vtp is the threshold of a pmos transistor) of the pmos transistors due to body effect (the bulk connection will remain at Vdd). This further reduces the threshold of the inverters of the cells, making it easier to write in the above-described manner.

The cell of FIG. 4 shows a fully differential read type cell. Nevertheless, this source connected cell can also be used with single ended reads, as in the cells of FIGS. 2(a) and (b), thereby reducing the transistor count to five and reducing the area of the cell accordingly.

PMOS source Connected Write Bitlines (PSWB)

An alternative implementation that works in a similar way as the embodiment of FIG. 4 is to connect the write wordline wwl to the nmos drive devices N_t, N_c and the write bitlines wbl_t, wbl_c to the pmos transistor devices P_t, P_c respectively. This is illustrated in FIG. 5.

In this embodiment, the write bitlines wbl_t, wbl_c are normally held at voltage Vdd and the write wordline wwl is normally held at gnd (ground). To write a value 0, the true bitline wbl_t is lowered to Vlow (e.g. 0.8V) and the write wordline wwl is raised to Vwwl (e.g. 0.4V).

It will be appreciated that removing the need for write access devices improves the leakage performance of the cell: there is no longer a path from the precharged bitline to the low data node via the access transistors.

In addition, write access devices are usually very small:
In order to keep the overall cell size small
To make the nmos beta ratio high enough to make the cell stable

Small devices such as these are more prone to device variations. Removing the write access devices from the cell therefore produces a large improvement in cell variability across a memory.

In the traditional 6T cell, weak access devices mean the pmos devices P_t, P_c also have to be small to ensure the cell can be written to. In the proposed new cells of FIGS. 4 and 5 this is no longer the case as the pmos transistors P_t, P_c can be larger without compromising the cell size. This has two benefits;
1. A further increase in static noise margin (SNM)
2. Further improvements in cell variability across the memory

In fact, a design trade-off can be made whereby some of the area gained with using a 5T source connected cell can be spent on further increasing devices sizes giving further improvements in SNM and variation.

Some Issues with Source Connected Write Bitlines

In source connected writes half-selected cells are created:
In the same column they are exposed to the voltage differential on the write bitlines.
In the same row they see the raised (p-source connected bitlines) or lowered (n-source connected bitlines) write wordline.

Both of these effects reduce the static noise margin of those half-selected cells. Of the two, the half selected column experiences the biggest drop in SNM. However, this reduction is better than that found in a half-selected prior art 6T cell.

### Layout of the NMOS Source Connected Write Bitline (NSWB) Cell

The physical layout of the source connected write bitline cells is topologically better than the standard 6T cell design. An example is given below in FIG. 6 which shows a single well boundary six transistor NSWB cell.

The read and write bitlines run vertically and the read and write wordlines run horizontally. All transistors run in the same direction (as opposed to the standard 6T cell which has orthogonal access devices). Each row is flipped in the X-axis so that the write bitline wbl_t, wbl_c and read bitline rbl_t, rbl_c contacts are shared.

One problem with this layout is that the inverter crossover to form the cell latch can potentially be difficult to create in practice, either requiring the use of metal2 or increased area or both. The topology of FIG. 7 gives better structure and makes it easier to connect the global signals. This shows a double well boundary 6T NSWB cell.

Again, each row is flipped in the X-axis. The advantages of this topology include:
Easier inverter cross couple implementation.
Only metal1 needed for inverter cross couple: avoiding vial and metal2 often seen in other cells and their associated yield hazards.
It is rotationally symmetric.
All transistors are in the same direction (in contrast, the access devices in traditional 6T cell are rotated).
All active area regions have the same area.
Easier global connections verses previous layout

One disadvantage is that two well boundaries (the box 20 indicated in dotted lines in FIG. 7 is the nwell in this example, which defines which transistors are pmos) within the cell could increase area.

Other layout techniques can be applied to reduce the area, for example, the layout of FIG. 7 would benefit from staggering adjacent cells. The cell pitch is set by the nmos transistor poly gate end overlap and poly space. By staggering the poly space rule is avoided and the limiting rule becomes gate end overlay and space from poly to active. FIG. 8 illustrates how two adjacent cells can be staggered in a double well boundary 6T cell.

It will be readily appreciated that a full layout investigation on a per manufacturing process basis would preferably be conducted before the most effective layout can be chosen.

A five transistor (5T) version of this topology (i.e. for a double well boundary 5T NSWB cell) is shown in FIG. 9. The cell is within the box 20 indicated in broken line; the cell to the right of this cell is rotated 180 degrees and the cell to the left is mirrored in the Y-axis. On the left hand edge of this cell staggering can be used to create an extremely compact arrangement.

### Improved Half-Selected Column SNM: Shared Write Bitlines

A method of reducing half selected bitlines on the source connected write bitline cell is to share the vertical bitlines as illustrated in FIG. 10.

For example, consider a p-source connected write bitline cell such as in FIG. 5. We shall call this cell “cell 1” and we shall call an adjacent cell “cell 2” and a next adjacent cell “cell 3”. We shall use the reference [1] to refer to parts of cell 1 and the reference [2] to refer to parts of cell 2. All write bitlines are held at a default voltage, Vdef, which is mid way between Vlow and Vdd. For example, if Vlow=0.8V and Vdd=1.2V typically, then Vdef=1.0V. When one wishes to write a value 1 to cell 2 the write bitline wbl_t[1] is raised and write bitline wbl c[1] is lowered. Cell 1 is not disturbed as we keep wbl_c[0] at Vdef and similarly cell 3 is not disturbed as we keep wbl_t[2] at Vdef.

Vdef does not have to be exactly half way between Vdd and Vlow. The SNM of the half selected cells may be minimized by having Vdef slightly lower or higher than the mid point.

In this scheme we cannot write to adjacent cells. In fact, cells being written to must be spaced apart by two unwritten cells. In the above example, the next cell that can be written to is cell 5. In practical terms, this dictates that the architecture have column multiplexing in place with a minimum of 4:1 (NB 3:1 would work, but normally column multiplexing is a power of 2 e.g. 2̂n, where n is 0, 1, 2 . . . ).

### Layout of the Shared Write Bitline Cell

The shared write bitline structure is best implemented as shown in FIG. 11 which illustrates layout of a p-source connected write bitline cell layout with shared write bitlines.

In this layout, the write bitlines wbl_t and wbl_c run vertically and are shared with adjacent cells as described above in the section entitled “Improved Half-selected Column SNM: Shared Write Bitlines”. The read bitlines run vertically within the column. A 5T version of this cell is easy to implement and allows the read bitline contact to be shared with the row below whose cells are rotated 180 degrees.

This cell is also a good candidate for staggering which would reduce the cell height.

### The Static 4T Cell: Orthogonal Source Lines

Alternative further embodiments of the inventions will now be described in detail in which the true and complement source connections to either the pmos or the nmos run orthogonally. At this point the notation bitline and wordline begin to lose their applicability and hereinafter these signal lines shall be referred to as ph (pmos source connection, horizontal), pv (pmos source connection, vertical), nh (nmos source connection, horizontal) and nv (nmos source connection, vertical).

P-Source Connected Orthogonal Line Static 4T cell (PSOL4T)

FIG. 12 illustrates a p-source connected orthogonal line static 4T cell. This CMOS SRAM cell comprises two cross-coupled inverters each comprising a pmos transistor P_t, P_c and an nmos transistor N_t, N_c, a first signal line nh connected to the sources of each of the nmos transistors, a second signal line ph, parallel to the first signal line, and connected to the source of one the true pmos transistor P_t, and a third signal line pv connected to the source of the other pmos transistor P_c, and the third signal line pv is orthogonally connected to the first and second signal lines ph,pv.

The p-source connected signals are by default driven to Vdd so they act as a normal supply. A write is affected by first raising the nh line to Vnhi on the row that one wishes to write to. In this example Vnhi=0.4V. Writing value 1 is achieved by moving pv low to Vplo which turns on the true pmos transistor P_t sufficiently to over-drive the true nmos transistor N_t and pull the true data node data_t high. In this example Vplo=0.8V. Similarly, a write 0 is achieved by moving ph low to Vplo.

There is a problem in moving ph low to Vplo to write 0: all the other cells on the row connected to both nh and ph will also have 0 written to them.

Alternatively, a ph and pv default voltage (Vdef) lower than Vdd can be set. In which case a write 1 is affected by moving ph high and pv low and a write 0 by moving ph low and pv high. If Vdd=1.2V and Vplo=0.8V one could set Vdef=1.0V. The advantage of this arrangement is that the half selected cells (on the rest of the row and the rest of the column) are exposed to smaller voltage variations e.g. Vdef=1.0V to Vplo=0.8V or Vhigh=1.2V. This can have benefits in keeping the SNM of the half selected cells at an acceptable level.

(It will be appreciated that the intermediate voltages quoted in the above examples will depend in each case on the power supply voltage level and the process used and are therefore approximate values given for example purposes only.)

But there is still the problem of writing both 0s and 1s to the same row of PSOL4T cells. Three alternative options describing how 1s and 0s can be written to cells in the same row are outlined below:

1. Using Sub-Wordlines

Using the default voltage scheme, divide the wordline nh into sub-wordlines and ensure in the SRAM architecture that only one cell in the sub-wordline is ever written to at any one time by moving only one of the pv signals connected to the cells in the sub-wordline to Vplo or Vhigh. Data to be written to the sub-wordline driver must also be provided so that ph, which is also divided into sub lines in the same way as nh, can be driven to either Vhigh or Vplo correspondingly.

2. A two Phase Write

Two-phase write waveforms for a PSOL4T cell with Vdef=Vdd are illustrated in FIG. 13. Start with ph=Vplo. If pv=Vplo as well, to write 1 then nothing will happen. If pv=Vhigh to write 0 then 0 will be written. Then ph is raised to Vphi. If pv=Vphi to write 0 then that 0 will stay as ph=pv=Vphi. If pv=Vplo to write 1 then 1 will be written. Both ph and pv can then return to Vdef.

Two-phase write waveforms for a PSOL4T cell with Vdef=1.0V are illustrated in FIG. 14. Start with ph=Vdef, pv=Vdef and nh=gnd. Then ph=Vplo and nh=Vnhi: if pv=Vplo as well then nothing will happen; if pv=Vhigh to write 0 then 0 will be written. At this point if ph and pv are Vplo the cell may be unstable; this does not matter because if so a 1 will be written subsequently which will correct any erroneous data. Then ph is raised to Vphi: if pv=Vplo a 1 will be written; if pv=Vphi nothing will happen as both ph and pv=Vphi so the 0 written will remain.

3. Write all 0 then Selectively Write 1s

Initially nh=gnd, ph=Vdef and pv=Vdef. Then nh=Vnhi and ph=Vplo is applied to write all zeros to the row. Then ph is raised to Vdd so ph=Vdd, pv=Vdd and nh=Vnhi, a stable condition. Then pv is lowered on the cells where a 1 is to be written so ph=Vdd, pv=Vplo and nh=Vnhi. Finally, both ph and pv can return to Vdef.

The waveforms shown in FIG. 15 shows this mechanism with Vdef=Vdd. The waveforms in FIG. 16 illustrates this mechanism with Vdef at a mid point, Vdef−1.0V. Both show a 1 being written. If a 0 is to be written pv is held at Vphi (i.e. pv=ph) in the second phase after the broken vertical line (see FIGS. 15 & 16) in both cases.

All solutions 1-3 have disadvantages: solution 1 creates architectural limitations and solutions 2 and 3 may have timing issues and complexity. These disadvantages are not, however, overwhelming and the solution that best fits the RAM architecture can be chosen.

Options 2 or 3 with Vdef set at a mid point between Vdd and Vplo offers the best half selected SNM but has more supply voltages to generate.

### Horizontal Source Signal Pairing

Most memories use column multiplexing to increase the area available to implement circuits that sit below the column. If all cells on the row have to be written to, this implies no such column multiplexing and therefore could be problematic. A method to circumvent this limitation is to use pairs of nh and ph source lines. This is illustrated in FIG. 17 which shows a horizontal source signal pairing scheme.

In such a scheme, either the nh[0] or nh[1] is selected along with either ph[0] or ph[1]. For the cell to be successfully written, it must be connected to both the selected nh and the selected ph. In this way one of every four cells on the row can be selected. The other half-selected cells on the row are only exposed to either the selected ph or nh, but not both. The disadvantage of this scheme is that four tracks per cell as well as a read wordline may be difficult to layout. However, this problem can be mitigated by sharing connections with adjacent rows.

### Layout of the Orthogonal Bitline Cell

Orthogonal bitlines can easily be added to the layout of a cell, as illustrated in FIG. 18 which shows schematically a single well boundary PSOL4T cell. This layout is based on the traditional 6T cell layout but with the access transistors removed. The rows above and below are mirrored in the x-axis Creating the cross couple in the cell can be difficult and in practice may require metal 2 or an increase in cell area.

Column multiplexing of 2:1 or 4:1 can be added by sharing the ph and/or nh connections with the rows above and below. This is illustrated in FIG. 19 which shows an array arrangement for a single well boundary PSOL4T cell. The vertical wires are in metal 2 and the horizontal wires are in metal 3 to ease contacting down to the transistors.

Using the alternative layout topology shown schematically in FIG. 20 is also possible. The only disadvantage with this layout is the ringed area 30 with the poly contact facing the poly gate end overlap of the adjacent cell. Depending on the layout rules, this may or not be an issue that leads to an increase in cell area.

The further alternative layout of FIG. 21 removes this issue but requires adjacent rows to share their ph connections. FIG. 21 shows schematically an improved double well boundary PSOL4T cell layout. The rows above and below can either be mirrored or unmirrored. In the latter case all the cells have exactly the same orientation across the entire array, which is beneficial for yield.

In the cell layout of FIG. 21 the ph connections are shared between adjacent rows. This is acceptable because a write will only occur on the row that also has its nh connection driven to Vnhi. The other row will be half selected. In order to prevent the half-selected row from also seeing an active write bitline, the pv connections must be split. This ensures that all half selected rows and columns only every see one active wordline or bitline. This can be combined with the horizontal source line pairing technique described above to increase the achievable column multiplexing. With the cell layout of FIG. 21 all these conditions can be met, as illustrated in FIG. 22 which shows schematically an array arrangement for an improved double well boundary PSOL4T cell.

The cell 40 highlighted in FIG. 22 is connected to ph<2>, nh<2> and pv<0>. (The 0, 1, 2 . . . refer to the 0^{th}, 1^{st}, 2^{nd} of each signal starting at the bottom left of FIG. 22.)

No other cell in FIG. 22 connects to more than one of these lines:
The third cell 42 in the top row shares its contact to ph<2>
The first cell 44 in the top row connects to ph<2>
The first cell 46 in the bottom row shares its contact to pv<0>
The first cell 48 in the middle row connects to nh<2>
The fourth cell 50 in the middle row connects to ph<2>

This minimises the SNM impact on half selected cells.

In a complete array, every fourth cell on the same row would connect to both ph<2> and nh<2> which means this array must have a 4:1 column multiplexer for reading and writing.

### Reading the PSOL4T Cell

How is a read operation conducted in the p-source connected orthogonal line 4T cell?

If one drives the ph line to vdd, precharge pv to vdd, then release pv and lower ph to <Vdd−Vtp:
If data_t=Vdd data_c=0 then the ph voltage will be transferred to data_t and transistor P_c will turn on, pulling down pv.
If data_t=0, data_c=vdd then the ph voltage will not transfer to data_t and pv will remain at its precharge voltage, Vdd

There are limits to this approach:
1. One cannot lower ph to far as one risks writing a 0 to the cell
2. The read swing voltage generated on pv stops building as it approaches Vph+Vtp
3. The read swing can be improved by driving the bulk of the pmos transistors P_t/c to Vph: this lowers the Vtp on the addressed wordline For this to work the pmos transistors n-well must run horizontally.
4. The start of the read as ph lowers before pv has a chance to lower is the worst case state for stability. As pv follows ph lower stability improves.

Point 4 offers some scope for optimization. The edge rate of ph can be adjusted so that the initial drop is fast, but does not go all the way to Vph. The rest of the drop can occur slowly, limiting the difference between voltage difference ph and pv to preserve the SNM during the read. This shape of curve tends to happen naturally as in driving ph, we are essentially discharging a capacitor from Vdd to Vph.

The lower ph goes, the greater the potential differential on pv. As pv will settle at Vph+Vtp the SNM in this state sets the minimum voltage on ph.

### N-Source Connected Orthogonal Line Static 4T Cell (NSOL4T)

The orthogonal line technique can of course be applied to the n-sources. This is illustrated in FIG. 23 which shows an n-source connected orthogonal line static 4T cell. Consider the PSOL4T circuit illustrated in FIG. 12. This CMOS SRAM cell comprises two cross-coupled inverters each comprising a pmos transistor P_t, P_c and an nmos transistor N_t, N_c, a first signal line nh connected to the source of the true nmos transistor N_t, a second signal line ph, parallel to the first signal line, and connected to the source of each of the two pmos transistors P_t, P_c, and a third signal line pv connected to the source of the other nmos transistor N_c, and the third signal line pv is orthogonally connected to the first and second signal lines ph,pv.

This cell can be written and read in almost exactly the same way as the p-source version of FIG. 12, although this time the ph line selects the row and the n lines are driven differentially with respect to ground. Exactly the same layout and array arrangement as the p-source cell of FIG. 12 can be used: the pmos and nmos are simply transposed by moving the wells.

### The Separate Source Static 4T Cell (SSS4T)

FIG. 24 shows a yet further possible embodiment of the invention. The cell shown in FIG. 24 shall be referred to as a “separate source static 4T (SSS4T) cell”. This cell comprises two cross-coupled inverters each comprising a pmos P_t, P_c and an nmos N_t, N_c transistor, a first pair of parallel signal lines ph, nh comprising a first line ph connected to the source of the true pmos transistor P_t and a second line nh connected to the source of the complementary nmos transistor N_c, and a second pair of parallel signal lines nv, pv comprising a first line nv connected to the source of the true nmos transistor N_t and a second line pv connected to the source of the complementary pmos transistor P_c. The two pairs of signal lines are orthogonal.

Thus, the SSS4T cell has all four transistor sources in the cell separately connected. The n-source signals run orthogonally, as do the p-source signals. This arrangement potentially reduces the voltages required to write to the cell as differentials are built up on both p-sources and n-sources.

### Layout of the Static 4T Separate Source Cell (SSS4T)

The SSS4T cell can be laid out in two alternative ways. This first way is illustrated in FIG. 25 which shows schematically the layout of a double well boundary SSS4T cell. An array of such cells is illustrated schematically in FIG. 26. To enable contacting, the vertical lines are in metal 2 and the horizontal lines are in metal 3.

The following conditions are required to select the highlighted cell 60 (which is the second cell from the left on the second row from the top, in FIG. 26) and write a 1 thereto: ph[3]=Vdd, pv[0]=Vplo, nh[3]=Gnd, nv[0]=Vnhi.

With the arrangement as shown in FIG. 26, only every fourth cell in the same column as the selected cell is exposed to more than one changing voltage from Vpdef or Vndef, minimizing the SNM impact of a read or a write. Crucial to this is the splitting of the PV signals into PV[0] and PV[1]. If this was not the case the cell above the selected cell would see two non-default signals: PV (PV[0] and PV[1] combined) and PH[1].

Splitting PV into PV[0] and PV[1] implies that one bit of the row memory address must be given to the column decoding so that the correct signal, PV[0] or PV[1] is driven for the required cell to be accessed.

This arrangement shares the contacts between the adjacent cells. This has implications in the row and column select. Other arrangements that achieve the goal of only one non-default signal in all other cells may also be possible. For example, the NV signals could be routed in a diagonal direction, either on an extra layer of metal or by threading the signal in metals 2 and 3. This is illustrated schematically in FIG. 27. The diagonal orientation of the route would allow only the cell at the intersection of the vertical, horizontal and diagonal active lines to be enabled. The disadvantage of this approach is that only one cell out of an array could be selected in this manner. To select multiple cells in a memory the memory cell array would have to be split into multiple sections that are separately addressed in this manner.

Multiple Ports with Source Connected Wordline With source connected reads, because write and read use separate paths (transistors), the proposed cell can be used to create a memory that can do simultaneous read and writes. When a read and a write wish to access the same cell, the read could be inconclusive or delayed and therefore so called write through operation (where a read tries to deliver the new data) would not be recommended.

The source connected read cell is ideal for creating multiple read ports: the read transistors can be replicated to create dual, triple etc. read ported cells.

Multiple write ports on the source connected write bitline cells are more difficult to implement: the traditional pair of access devices could be used in combination with the new write mechanism to create a dual write ported cell. Further write ports would require further pairs of access transistors.

### Supply Voltage Generation

The extra supply voltages proscribed in any of the source connected cells can be generated using voltage regulators from Vdd. These voltages can be accurately generated and distributed. The voltages can be created from an on chip reference such as a band gap.

However, the voltages needed are in fact proportional to the Vts (either Vtn or Vtp), of the transistors in the cell. A superior approach is to base the voltage supplies on these Vts so that as the Vts vary, for example with temperature, the supplies vary in the same way.

With p-source connected bitlines the voltage required to cause a write will be Vdd−Vtp−Vmargin. As Vtp, the pmos threshold voltage, will vary with process and temperature, the best solution is to create a reference based on Vtp. This is illustrated in FIG. 28 which shows a Vdd−Vtp voltage generator. The Vmargin can be adjusted by adjusting the reference current: increasing the reference current increases the voltage margin.

Variations in the Mvtp device in FIG. 28 with respect to the pmos devices in the cells could cause a non-representative voltage to be created at Vref. One solution is to instantiate multiple copies of this transistor so the reference becomes an effective average of these multiple transistor Vtp values. Various refinements of this basic design can be made as follows:
Divide the resulting voltage to create Vdef and Vplo for the orthogonal write bitline cell.
Add an nmos pull down device to the Vref node to prevent it rising above the reference.

There would of course be an area overhead associated with this extra circuitry, although on modern chips such regulator circuits often already exist. In addition, the current that needs to be supplied by these regulators is small, which simplifies their design and reduces their area.

Supplies Greater than Vdd

The voltage differentials for writes and reads to source connected cells could also be created by using voltages above Vdd. For example, in a 5T or 6T p-source connected write bitline cell, wbl_t could be driven to Vphi=Vdd+Vtp and wbl_c to Vplo=Vdd−Vmargin to write a 1. Vphi could be generated from an alternative supply, higher than Vdd, which is often available on modern chips.

Alternatively Vphi can be generated by a charge pump or even by a boot-strap circuit.

If Vphi goes higher than Vdd+Vtp it will turn on non-selected cells in the column which therefore clamp the bitline to Vdd+Vtp.

The advantage of using supplies greater than Vdd is that the SNM degradation of the half-selected cells is minimized.

### SUMMARY

Various new SRAM cell designs and layout topologies have been described above.

These innovations amount to a step change in SRAM design, offering (among them) the following benefits (among others):
Smaller cell size: 6T differential and especially 5T or 4T single ended options
Faster speed: better read current, quicker differential build on 6T or 5T versions
Options for concurrent read and write access on 6T or 5T versions.
Operates at lower voltages: suitable for low power applications for 7T, 6T and 5T
Leakage reduction: much better standby current specs.
Area reduction beyond the cell: more cells per bitline simplifies array structure saving area on 6T or 5T versions.
Better layout: superior extremely uniform topology, better manufacturing yield expected.
Improved variability: removing small, high variability access and load devices on 6T, 5T and 4T cells.
Better half-select stability gives better yield: improved static noise margin in half selected rows and columns.

It will be readily appreciated that various modifications and improvements to the above-described embodiments are possible within the scope of the invention. For example, the various source connected read structures described with reference to the cells shown in FIGS. 2 to 5 can be additionally applied to any of the static 4T cells with orthogonal signal lines shown in FIGS. 12, 23 and 24.

Furthermore, with reference to the “orthogonal signal line” cells of FIGS. 12, 23 and 24, in further possible modified embodiments the horizontal lines nh or ph and vertical lines nv or pv can swap roles. Thus on a square array of cells it would be possible to read or write all the bits in a certain column. This can be useful e.g. to set all the bits in a set of data to be a certain value, or potentially in matrix manipulation where rotating, or transposing the data in this way is used in some signal processing and compute algorithms.

1. A CMOS SRAM cell comprising two cross-coupled inverters each cross-coupled inverter comprising a pmos and an nmos transistor, a first signal line connected to the sources of each of the nmos transistors, a second signal line, parallel to the first signal line, and connected to the source of one of said pmos transistors, and a third signal line connected to the source of the other of said pmos transistors, wherein the third signal line is orthogonal to the first and second signal lines.

2. A CMOS SRAM cell comprising two cross-coupled inverters each cross-coupled inverter comprising a pmos and an rums transistor, a first signal line connected to the sources of each of the pmos transistors, a second signal line, parallel to the first signal line, and connected to the source of one of said nmos transistors, and a third signal line connected to the source of the other of said nmos transistors, wherein the third signal line is orthogonal to the first and second signal lines.

3. An array of substantially identical CMOS SRAM cells according to claim 1, wherein the array includes at least four parallel signal lines for accessing different cells in a row of the array, wherein each line of a first pair of said signal lines is connected to the sources of respective ones of the nmos transistors in said row and each line of a second pair of said signal lines is connected to the sources of respective ones of the pmos transistors in said row.

4. (Currently amended. A CMOS SRAM cell comprising two cross-coupled inverters each cross-coupled inverter comprising a pmos and an nmos transistor, a first pair of parallel signal lines comprising a first line connected to the source of one of the pmos transistors and a second line connected to the source of one of the nmos transistors, and a second pair of parallel signal lines comprising a first line connected to the source of the other of said nmos transistors and a second line connected to the source of the other of said pmos transistors and wherein said two pairs of signal lines are orthogonal.

5. A cell according to claim 1, wherein the cell further includes at least one read transistor for accessing the cell during read operations thereon.

6. A CMOS SRAM cell comprising two cross-coupled inverters, a pair of bitlines for writing data to the cell, and at least one further bitline for reading data from the cell.

7. A cell according to claim 6, wherein the cell comprises a single said further bitline for reading data from the cell.

8. A cell according to claim 7, wherein the cell further comprises a pair of write transistors for accessing the cell during write operations on the cell, and a further read transistor via which said single further bitline accesses the cell during read operations on the cell.

9. A cell according to claim 8, wherein the cell further includes a write wordline for controlling the pair of write transistors and a separate read wordline for controlling the read transistor.

10. A cell according to claim 9, wherein said read wordline is connected to the source of the read transistor and said read bitline is connected to the drain of the read transistor.

11. A cell according to claim 8 wherein the read transistor is a pmos transistor.

12. A cell according to claim 8, wherein the read transistor is a nmos transistor.

13. A cell according to claim 8, wherein the cell comprises a pair of said further bitlines for reading data from the cell.

14. A cell according to claim 13, wherein the cell further comprises a pair of write transistors for accessing the cell during write operations on the cell, and a further pair of read transistors via which said pair of further bitlines access the cell respectively during read operations on the cell.

15. A cell according to claim 14, wherein the cell further includes a write wordline for controlling the pair of write transistors and a separate read wordline for controlling the pair of read transistors.

16. A cell according to claim 15, wherein said read wordline is connected to the source of each of the read transistors and each said read bitline is connected to the drain of a respective one of the read transistors.

17. A cell according to claim 14, wherein the read transistors are each pmos transistors.

18. A cell according to claim 14, wherein the read transistors are each nmos transistors.

19. A cell according to claim 6, wherein each cross-coupled inverter comprises a pmos transistor and a complementary nmos transistor and the two write bitlines are connected to the sources of two like transistors respectively of the inverters.

20. A cell according to claim 19, wherein the cell further includes a write wordline connected to the sources of the other two like transistors respectively of the inverters.

21. A cell according to claim 20, wherein the cell further comprises at least one read transistor via which the or each said bitline for reading data from the cell accesses the cell during read operations on the cell.

22. A cell according to claim 21, wherein the cell further includes a dedicated read wordline for controlling the or each said read transistor.

23. A cell according to claim 22, wherein said read wordline is connected to the source of the or each said read transistor and the or each said bitline for reading data from the cell is connected to the drain of a respective said read transistor.
